(19) United States
(12) Patent Application Publication
(10) Pub. No.: US 2016/0124031 A1
(43) Pub. Date: May 5, 2016

(54) SMART MULTI-PURPOSE MONITORING SYSTEM USING WAVELET DESIGN AND MACHINE LEARNING FOR SMART GRID APPLICATIONS

(71) Applicants: Walid G. Morsi Ibrahim, Oshawa (CA); SAMI ALSHAREEF, Oshawa (CA); SAURABH TALWAR, Oshawa (CA)

(72) Inventors: Walid G. Morsi Ibrahim, Oshawa (CA); SAMI ALSHAREEF, Oshawa (CA); SAURABH TALWAR, Oshawa (CA)

(21) Appl. No.: 14/532,621

(22) Filed: Nov. 4, 2014

(51) Int. Cl. G01R 19/25; G01R 19/10; G01R 31/02

(52) U.S. Cl. CPC G01R 19/2513; G01R 31/02; G01R 19/10

(57) ABSTRACT

A new voltage-based index is formulated in the time-frequency domain (using wavelets) and the energy of the wavelet coefficients associated with the change in mean voltage is used to extract the islanding features rather than using the energy of the wavelet coefficients themselves as in the prior art. Procrustes analysis is used to design the new wavelet, namely WGM1.0, by only satisfying the minimum properties on the wavelet filter of length 6 (i.e., six coefficients). Machine learning is then used to develop islanding classification models based on the calculated voltage index and the new wavelet. Two classifiers are used for the present invention: Support Vector Machine (SVM) and Ensemble Tree classifier (ETC).

### FIELD OF THE INVENTION

The present invention is related to electrical power distribution systems and more specifically to monitoring and detecting electrical power signals pattern using single point monitoring and applied to the smart electric grids applications such as islanding phenomenon that may occur in electric power distribution systems embedded with distributed generation.

### BACKGROUND OF THE INVENTION

Remote schemes are based on communication between the utility and distributed generators (DG), but they suffer high implementation costs. On the other hand, local islanding schemes can be further divided into active and passive methods. Active methods inject disturbance into the system, while passive methods use electric signals at the DG. Active methods may result in poor power quality (PQ) and also suffer high installation costs. On the other hand, passive methods are inexpensive, easy to implement, and do not affect PQ. However, the main limitation of passive methods lies in the range of conditions where the island may not be detected, known as a non-detection zone (NDZ).

Previous work in the field of islanding detection in distributed generation (DG) systems has used impedance, power, and frequency to detect the islanding of DG by extracting transient features either in time or frequency domain. The application of wavelet transform for islanding detection has been used previously and can be separated into non-energy and energy-based indices.
1) Non-Energy-Based Indices: there exist in the prior art systems that have used wavelet coefficients of voltage and frequency signals to detect islanding by comparing the values of these coefficients to an arbitrarily chosen threshold. Others have used the harmonic contents of output power in wavelet domain to identify islanding. All previous work has applied thresholds after computing the wavelet coefficients. The direct use of an arbitrary threshold may increase the chances of misdetection and hence could possibly lead to nuisance tripping, which justifies the use of wavelet coefficient energy-based indices.
2) Energy-Based Indices: The prior art shows systems that have used the energy of wavelet transforms-coefficients of voltage signal at level 2 and Daubechies 4 to detect islanding by comparing the energy values of wavelet coefficients to a pre-determined threshold. Other studies have used the energy of negative sequence voltage coefficients at the first decomposition level to detect islanding in a standalone power system. Furthermore, the energy of the wavelet coefficients of voltage and current in all three phases has also been used.

### SUMMARY OF THE INVENTION

The invention relates to the electrical power engineering field and in particular electrical power signal pattern detection. Many applications in the electric field require a robust method to detect certain phenomena by finding unique signatures of the desired patterns.

For example, fault detection, identification and localization needed electric power systems protection is a fairly complex process and requires a robust identification of the electrical signals features to ensure correct detection of the fault.

Another example is power quality disturbance classification which requires identification of different disturbances to the voltage waveforms through monitoring. Also the non-intrusive energy monitoring for smart grid applications especially for energy management and early detection of appliances and equipment for predictive maintenance.

Another important application is the detection of islanding operation of generators in power system.

The currently available methods rely mainly on the use of electrical signal filtering to extract the desired signal for detection application. The filters used in most of the existing methods are based on different applications in different fields such as communications and signal processing and not electrical power system.

In the known art, most researchers rely on wavelet filters previously designed for specific applications in communications and image processing. There is a need for a new wavelet that is suitable for islanding detection. The new wavelet must satisfy minimum properties of the wavelet filter and avoid other redundant requirements that may not be useful for the islanding problem such as imposing specific number of zero moments which increases the number of coefficients and hence increases the processing time. Moreover, since typically in distribution systems the voltage does not contain many variations as the current, there is a need for a detection approach that uses only the voltage signal to extract the transient features through a wavelet based energy index while being sensitive to the islanding operation and immune to other disturbances.

Unlike previous work on islanding detection utilizing previously designed wavelets in other fields the present invention uses a new wavelet specifically designed for electrical power applications and in particular islanding detection of DG for passive methods of islanding detection using only a voltage signal. A new voltage-based index is formulated in the time-frequency domain (using wavelets) and the energy of the wavelet coefficients associated with the change in mean voltage is used to extract the islanding features rather than using the energy of the wavelet coefficients themselves as in the prior art. Procrustes analysis is used to design the new wavelet, namely WGM1.0, by only satisfying the minimum properties on the wavelet filter of length 6 (i.e., six coefficients). Machine learning is then used to develop islanding classification models based on the calculated voltage index and the new wavelet. Two classifiers are used in present invention: Support Vector Machine (SVM) and Ensemble Tree classifier (ETC).

### BRIEF DESCRIPTION OF THE DRAWINGS

Embodiments herein will hereinafter be described in conjunction with the appended drawings provided to illustrate and not to limit the scope of the claims, wherein like designations denote like elements, and in which:

FIG. 1 shows a modified IEEE 13 bus standard test system;

FIG. 2 shows a low-pass and high-pass filters at the decomposition and reconstruction side of the WGM1.0 filter bank;

FIG. 3 shows the steps in computing the wavelet mean voltage energy-based index; and

FIG. 4 shows a performance evaluation of SVM and ETC. (a) SVM, (b) ETC (Bagging), (c) ETC (Boosting), and (d) Recall values for SVM and ETC.

### DETAILED DESCRIPTION OF THE DRAWINGS

In wavelet transform (WT), the scaling and wavelet functions are:

Scaling Function:φ(t)=Σₖh₀(k)\sqrt{2}φ(2t−k) (1)

Wavelet Function:ψ(t)=Σₖh₁(k)\sqrt{2}ψ(2t−k) (2).

where h₀(k) and h₁(k) are the low and high pass filter coefficients respectively. To design a wavelet, sufficient conditions on the filters that stem from their properties must be satisfied. The present invention uses three properties of low pass filter representing minimum conditions as the designing criteria for the length 6 filter (i.e., six coefficients).

1) Normalization:

Σₖh₀²(k)=1

h₀²(0)+₀²(1)+h₀²(2)+h₀²(3)+h₀²(4)+h₀²(5)=1 (3)

2) Double shift orthogonality:

Σₖh₀(k)h₀(k−2n)=0 for n≠0

h₀(0)h₀(2)+h₀(1)h₀(3)+h₀(2)h₀(4)+h₀(3)h₀(5)=0 (4)

h₀(0)h₀(4)+h₀(1)h₀(5) (5)

3) Low pass:

Σₖ(−1)^{k}h₀(k)=0

h₀(0)−h₀(1)+h₀(2)−h₀(3)+h₀(4)−h₀(5)=0 (6)

The parameters α and β range between [−π, +π] and the Daubechies wavelets are only special cases in which α and β take specific values; for example, the choice of α=1.359803732 and β=0.782106384 for the length 6 filter leads to Daubechies of order three (DB3). However, other choices of α and β generate other wavelets. Exploring the full range [−π, −π] for both α and β leads to a set of new wavelets. To ensure proper wavelet selection, each generated wavelet must be compared with the island signal (preferably the most challenging island signal to detect, i.e., near-zero mismatch between DG and local loads) and the results are compared.

Procrustes analysis is used to compare a set of configurations (shapes) by finding the best transformation parameters that minimize the differences between the compared shapes. The island signal is set as the target shape U={u₁, u₂, . . . , uₘ} while the wavelet function W={w₁, w₂, . . . , wₘ} represents the comparison shape. The transformed shape V={v₁, v₂, . . . , vₘ} can be calculated from:

V=bWT+c (7)

Procrustes analysis finds the transformation parameters (b, T, and c for scaling, rotation/reflection and translation respectively) to minimize the goodness-of-fit criterion which is measured by the sum of squares error (SSE) between the target shape U (the island signal) and the transformed shape V.

minΣᵥ(uᵥ−vᵥ)²,v=1, . . . ,m (8)

A dissimilarity index ranges between 0 and 1, measures the ratio between the sum of the squared deviation between the target and the comparison shape with the sum of the squared deviation of the target shape from its mean μ is used.

$$d = \frac{{\sum }_{v} {( {u}_{v} - {v}_{v} )}^{2}}{{\sum }_{v} {( {u}_{v} - μ )}^{2}} \qquad ( 9 )$$

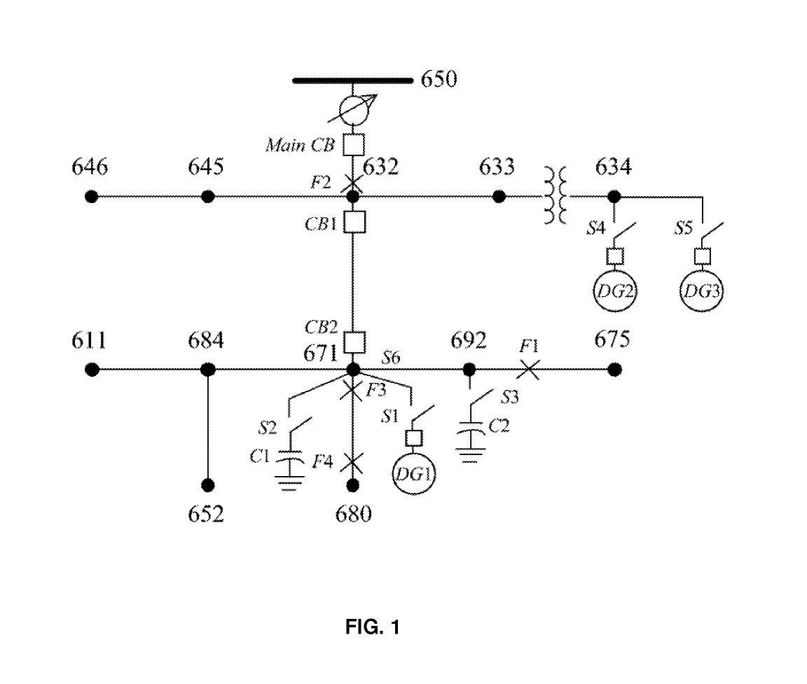

Values of d close to zero indicate high similarity while values close to 1 reflect large dissimilarity between the compared shapes. The goal is to find the wavelet that will provide the lowest value of d and hence determine the filter coefficients. FIG. 1 shows the single-line diagram of the IEEE 13-bus standard test system after being modified by adding DG and capacitors. When switch “S1” is closed, the system is energized from the substation (bus 650) and from only DG1 at bus 671. Appendix I lists the data for the DG.

In the case when the main circuit breaker (Main CB) is open, disconnecting the system from the main grid, an island is formed. Here, DG1 is supplying the load in the island which has been adjusted to closely match the power from the DG and hence this case can be considered an island operation at near-zero power mismatch (INZM). The three-phase voltages at bus 671 (PCC) is sampled at a rate of 7.68 kHz (128 samples per 60 Hz cycle) and the mean three-phase voltage is computed in (10) for each sample. vₘₑₐₙ can be calculated as follows:

$${v}_{mean} ( n ) = \frac{( {v}_{R} ( n ) + {v}_{S} ( n ) + {v}_{T} ( n ) )}{3} \qquad ( 10 )$$

where R, S and T denote the phase labels. The choice of this sampling rate satisfies Shannon's theorem, which states that the maximum frequency that can be assessed must equal half the sampling frequency. Given the chosen sampling frequency of 7.68 kHz and the dyadic nature of DWT a frequency width of 120 Hz in the approximation sub-band leads to five decomposition levels. The mean voltage signal is then set as the target U shape and is compared to each of the new wavelets resulting from changing the parameters α and β. The shape comparison is performed using Procrustes analysis and the wavelets with low dissimilarity index are determined along with their low pass filters. Table I lists the d-values for four new wavelets with the lowest d-values among the 400 wavelets generated when considering the full range [−π, +π] for both α and β. From Table I, it can be inferred that the first new wavelet (with short name WGM1.0) scores the lowest d-value and hence can be considered as the closely matching wavelet to the island signal. Since the high pass filter h₁(k) is the alternating flip of the low pass filter h₀(k), after determining the low pass filter coefficient of WGM1.0 the high pass filter coefficients can be found from:

h₁(k)=(−1)ⁿh₀(N−k) (11)

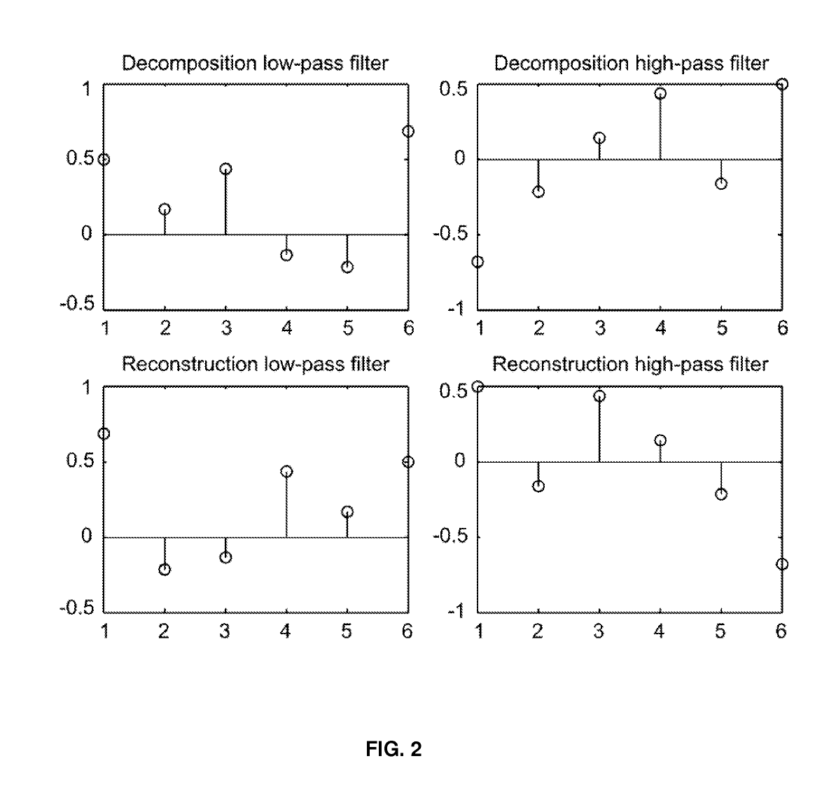

Table II lists the numerical values of the low and high pass coefficients of WGM1.0, while FIG. 2 shows the filter coefficients at both the reconstruction and analysis sides.

Starting from the mean sampled voltage vₘₑₐₙ (n) of the three-phases defined in (10) and measured at the point of common coupling (PCC) where the DG is tied to DS, time-frequency representation of the mean voltage signal in the wavelet domain can be mathematically formulated as:

$${v}_{mean} ( j , n ) = {\sum }_{j = 1}^{J} ( {\sum }_{i = 0}^{N / {2}^{i} - 1} 〈 {v}_{mean} , {ψ}_{j , i} 〉 {ψ}_{j , i} ( n ) ) + {\sum }_{i = 0}^{N / {2}^{i} - 1} 〈 {v}_{mean} , {φ}_{j , i} 〉 {φ}_{j , i} ( n ) ) \qquad ( 12 )$$

where J is the approximation level and j refers to the decomposition level index such that j=1, . . . , J. The present invention does compute the wavelet coefficients of both voltage and current as in the prior art, only voltage signal is used in the present invention. Moreover, applying wavelet to mean voltage instead of the three-phase voltage signals, reduces the number of signals to use to be one (i.e., mean voltage of the three-phases) instead of six (i.e., voltage and currents of the three-phases). Therefore the proposed approach requires only 2(ln) operations which is six times less compared to other approaches utilizing both voltage and currents signals that require 12(ln) operations.

The convolution of the basis wavelet functions (ψ and φ with the mean voltage signal vₘₑₐₙ(n) gives the detail and approximation level coefficients cD and cA respectively.

CDⱼ⁽ⁱ⁾= [symbol] vₘₑₐₙ,ψ_{j,i} [symbol] and cAⱼ⁽ⁱ⁾= [symbol] Vₘₑₐₙ,φ_{j,i} [symbol] (13)

with i=0, . . . , N/2^{j}−1 and N is the signal length, with i being used to refer to the index of the wavelet coefficients. The change in the wavelet coefficients of the mean voltage at the detail and approximation levels can be defined as:

COMVⱼ^{D}(i)=cDⱼ(i)−cDⱼ(i−1) (14)

COMVⱼ^{A}(i)=cAⱼ(i)−cAⱼ(i−1) (15)

The energy of the change of the wavelet coefficients of the mean voltage is computed as:

E_{COMV}_{ⱼ}_{^{D}}=Σ_{I}|COMVⱼ^{D}(i)|²,

E_{COMV}_{ⱼ}_{^{A}}=Σ_{I}|COMVⱼ^{A}(i)|² (16)

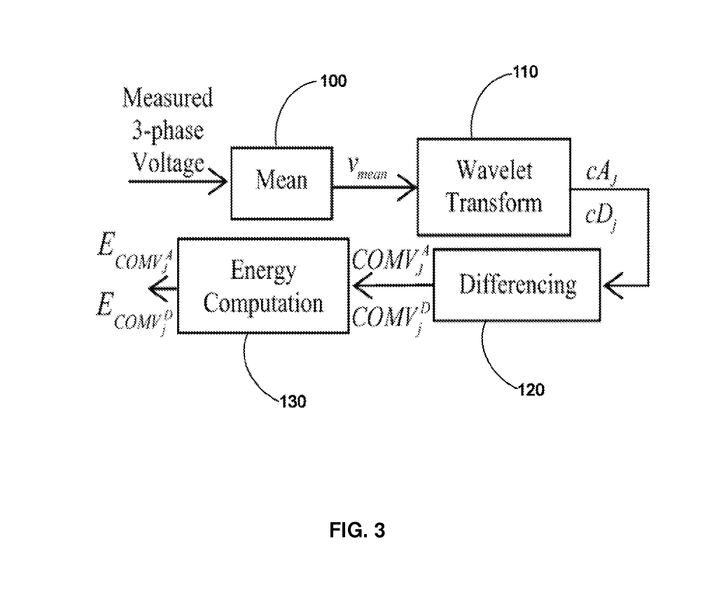

FIG. 3 shows a block diagram outlining the process of computing the change in the energy of wavelet coefficients of the mean voltage index (E_{comv}) at both the approximation and detail levels starting from the measured voltage signal. Discrete wavelet transform is applied to the mean voltage computed in (10) hence extracting the approximation (cAJ) and details (cDJ) voltage coefficients as in (12). The change in voltage coefficients (COMV) is then calculated using the differencing equations in (14) and (15). The energy of the change in wavelet coefficients of the voltage (E_{comv}) at the approximation and details is then computed using (16). As the figure implies, the “differencing” block expressed mathematically by (14)(16) is to ensure that the energy of the change in the wavelet coefficients is computed rather than the energy of the wavelet coefficients themselves. This is to ensure that the proposed mean voltage index (E_{comv}) only retains the features resulted from a change due to transient rather than other features resulted from steady-state disturbances (i.e., harmonics) in which no change occurs.

This classification technique mainly relies on constructing a decision boundary to separate the training instances into their respective classes. For most practical problems, it may not be feasible to find a linear decision boundary that separates the data in the original space and hence a transformation χ is needed to map the training instances xᵣ (r=1, . . . , I where xᵣ ε Rⁿ) from their original space into another transformed space, where a linear decision boundary can be applied. This classifier is known as nonlinear SVM and its learning task can be mathematically formulated as the following optimization problem:

min_{w,b,ξ}1/2w^{T}w+CΣᵣ₌₁^{l}ζr (17)

Subject to yᵣ(w^{T}χ(xᵣ)+b)≧1−ζᵣ and ζᵣ≧0 where ζᵣ represents the penalty of misclassifying the training instances, are the slack variables and yε{1, −1}^{l}. For the present invention, radial basis function (RBF) is used as the kernel function K (xᵣ,xₛ)=χ(xᵣ)^{T} χ(xₛ) to perform the transformation described above for non-linear SVM.

K(xᵣ,xₛ)=e^{(-γ∥x}^{ᵣ}^{-x}^{ₛ}^{∥}^{²},γ>0 (18)

A decision tree classifier builds a model by finding the best split among the attributes using an impurity (Gini) index.

Gini(t)=1−Σ_{η=0}^{c-1}[p(η|t)]² (19)

where p(η|t) is the fraction of instances belonging to class η at a given t node of the decision tree. The present invention uses an ensemble of decision trees that is constructed from training instances and is used to classify unseen (test) data according to the following majority voting scheme. Given a test instance x, the ensemble prediction C*(x) made by combining the predictions of k individual decision tree Cᵢ(x), i=1, . . . , k is: C*(x)=Vote(C₁(x), C₂(x), . . . ,Cₖ(x)). The present invention uses ETC based on manipulating training sets such as “Bagging” and “Boosting”. The main difference between “Bagging” and “Boosting” is that in the former the sampling of the training data is con-ducted with replacement, while in the latter the sampling is adjusted to allow the classifier to focus more on those training cases that are not easy to classify.

The classification accuracy (τ) of a model, which is defined as the ratio between the unseen records correctly predicted by a model and the total number of unseen records, has been extensively used to assess the performance of classifiers. How-ever, in case of islanding detection, the class of islanding cases may be considered rare compared to the majority class which includes the non-islanding cases (e.g., capacitor switching, and large motor staring, etc.) since the frequency of occurrence of an island is lower compared to other non-islanding cases which might occur on a daily basis. On the other hand, if an island occurs, it must be detected and hence, despite being a rare event compared to non-islanding cases, it must be correctly classified and detected by the model. This creates imbalance in the data set; thus, the islanding problem can be described as of class imbalance type. For this reason, the accuracy measure may not be well suited for the islanding problem and therefore alternative metrics such as precision (p), recall (r), and F-measure are used in this study to assess the performance of both SVM and ETC to detect island operation of DG in distribution systems.

$$p = \frac{TP}{TP + FP} , \\ r = \frac{TP}{TP + FN} , \\ F - measure = \frac{2 rp}{( r + p )} \qquad ( 20 )$$

where true positive (TP) is the number of islanding cases correctly predicted by the model, false positive (FP) is the number of non-islanding cases wrongly predicted as islanding cases and false negative (FN) is the number of islanding cases wrongly predicted as non-islanding cases by the model.

The modified IEEE 13-bus system shown in FIG. 1 is used to simulate different islanding (ILND) and non-islanding (NILND) cases to be used in the training and testing sets. To simulate ILND cases, the main CB is used to disconnect the grid, hence leaving DG in an island. Active and reactive power mismatch between DG capacities and local loads within the island ranging between −20% and +20%, are used to simulate different operating conditions for each of the following ILND scenarios listed in Table III.

The non-islanding cases mainly consist of faults and non-fault scenarios to simulate different operating conditions and different configurations on the studied test system. Four fault locations marked (x) in FIG. 1 and labeled (F1, F2, F3, and F4) are used to simulate both ground and non-ground faults, considering all possible combinations among phases for single line, double line and three-phase faults. Fault impedances, ranging from 0.001Ω to 100Ω, are also considered for each type of fault and for each fault location. The non-fault cases simulating different operating conditions include both capacitors (C1 and C2) switching using S2 and S3 at buses 671 and 692 respectively, large motor staring at bus 671, light and heavy load switching at bus 671. The disconnection of feeder (692-675) by opening switch S6 is used to simulate a topology change on the studied distribution system. In order to illustrate the detection capability of the proposed COMV index, the energy of the change in the wavelet coefficients (E_{COMV}) of the mean voltage signal computed using (14)-(16) is calculated and a normalized energy index (NEI), defined in (21) as the ratio of the computed wavelet coefficients' energies in both ILND (WCE_{ILND}) and NILND cases (WCE_{NILND)}, is developed. Large values (greater than one) of NEI indicate high sensitivity of the proposed COMV index to detect ILND cases compared to NILND cases.

$$NEI = \frac{{WCE}_{ILND}}{{WCE}_{NILND}} \qquad ( 21 )$$

The ILND cases involving DG1 alone as the power source in the island (first scenario in Table III) are used mainly for training. When DG2 is connected (scenario 2 in Table III), half of the ILND cases are used for training while the other half is used for testing. All ILND cases involving DG3 (scenario 3 in Table III) are used only for testing. The NILND cases for both faults and non-fault scenarios in the presence of DG1 are used for training. All these NILND cases are re-simulated but this time, when considering both DG1 and DG2, to be used for testing. Each training and testing set consists of 130 ILND and 343 NILND cases, totaling 473 cases which represent the number of observations in the data sets. The attributes of the data sets are the approximation and details and therefore each training and testing data set is represented by a matrix of 473 observations×6 wavelet levels.

The feature vector contains the energy of the change in the mean voltage for all six wavelet levels and therefore the entries of the training and testing data sets represent the numerical values of (E_{comv}) index as calculated in (16). Preliminary analysis has shown that for the majority of the cases except some single-phase faults, the valuable information contained in the approximation level can successfully separate islanding and non-islanding cases. As in any machine learner, the next step is to allow the classifier to learn the pattern from other wavelet levels through a training set and then assess its performance through a testing set. For that purpose, the training set is used first to train both SVM and ETC and to develop the classification models. The testing set is then used to assess the performance of both classifiers for unseen data using F-measure as described earlier.

The present invention was evaluated with comparable wavelets in the prior art. Seven wavelets namely Coiflet3 (COIF3), Coiflet5 (COIFS), Daubechies4 (DB4), Daubechies10 (DB10), Symlet4 (SYM4), Symlet8 (SYM8), and Symlet10 (SYM10), and the newly designed wavelet (WGM1.0) of the present invention, are considered in this study. Since the purpose of this section is to evaluate the performance of the eight wavelets, the same training/testing set consisting of the same situations is presented to each wavelet and is used to develop the corresponding model using SVM and ETC. The evaluation metrics (accuracy and F-measure) are computed for all the models developed and are compared.

Support Vector Machine (SVM) Classifier: Let us consider SYM10 (as an example). The model is developed by finding the parameters and by solving (17). This model is then used to predict the ILND/NILND cases from the testing set, which represents unseen data to the classifier. Table IV shows the confusion matrix summarizing the number of testing cases (or instances) that are correctly or incorrectly classified by the model, using SYM10. The counts in the con-fusion matrix are then used to calculate the accuracy (τ) as in (22), precision (p), recall (r), and F-measure according to (20).

$$τ = \frac{( TP + TN )}{( TP + FN + TN )} \qquad ( 22 )$$

According to the counts in the confusion matrix the model accuracy is 0.907. According to (20) the model precision, recall and F-measure are 1, 0.69 and 0.81 respectively. Low recall values reflecting the number of ILND cases correctly classified with respect to those that are misclassified, is reflected on the F-measure value which explains the difference between accuracy (0.907) and F-measure (0.8182).

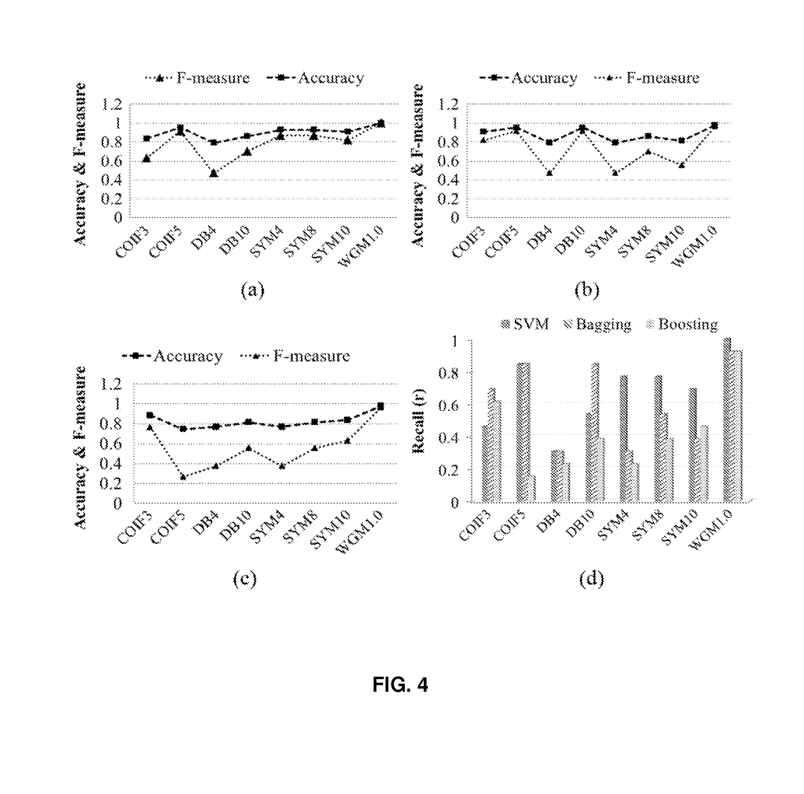

The same procedure is applied to the rest of the wavelets and the results of both evaluation metrics are plotted in FIG. 4(a). It can be inferred that in general the accuracy measure overestimates the performance of the classifier, providing above 80% accuracy for all wavelets.

However, in case of F-measure some wavelets (COIF3, DB4, and DB10) actually show poor performance (below 80%). The plot also shows that WGM1.0 is the only wavelet that provides the highest value of both accuracy and F-measure, indicating that its pattern closely matches the ILND signals.

Table VI lists the upper and lower bounds obtained from a standard Z-test at a confidence level 95% (α=0.05, Z_{α/2}=1.96) performed for Q=473 observations for all SVM models developed using eight wavelets considered for the present invention. Equation (23) is used to compute the upper and lower bounds reflecting the 95% confidence level which is listed in Tables V-VII.

$$\frac{2 \times Q \times τ + {Z}_{α / 2}^{2} \sqrt{{Z}_{α / 2}^{2} + 4 \times Q \times τ - 4 \times Q \times {τ}^{2}}}{2 ( Q + {Z}_{α / 2}^{2} )} \qquad ( 23 )$$

where Q is the number of observations and T is the model accuracy defined in (22).

FIGS. 4(b)-4(c) show the accuracy and F-measure plots for both ensemble methods: Bagging and Boosting (AdaBoost) with Tables VI and VII listing the corresponding confidence intervals computed using (23). The accuracy of ETC (Bagging) method for all wavelets is above 80% and is considerably higher than that of ETC (AdaBoost) since bagging works on reducing the variance in the training set by giving all instances (test case) the same chance (sampling with replacement).

On the other hand, AdaBoost has lower F-measure values compared to Bagging due to low recall values, as shown in FIG. 4(d). Both ETC models using WGM1.0 show the highest accuracy and F-measure, confirming the results obtained using SVM and indicating that the new wavelet (WGM1.0) significantly improves the performance of the ILND detection classifier.

Boosting adjust the sampling to focus more on cases that are difficult to predict, which explains the variance in recall values for the seven wavelets (COIF, DB, and SYM) shown in FIG. 4(d). Bagging has higher recall values compared to boosting indicating that the former has very few misclassified instances. Both ensemble methods (Bagging and Boosting) provide the same recall values (0.923) in case of WGM1.0, which is also considered relatively higher compared to recall values associated with the other wavelets, indicating that the new wavelet has significantly reduced (or even eliminated) the variance associated with the models developed by both by the large variance between accuracy and F-measure values FIGS. 4(a)-4(c).

However, when using other wavelets (for example, COIF5 and SYM4) it has been noticed that some of the islanding cases involving the inverter-based DGs are incorrectly classified as non-islanding cases. It can also be noticed that the overall highest recall value of 1.0 is associated with WGM1.0 when using SVM [C=1.6056 and γ=0.3248 obtained by solving (17) using Genetic Algorithm (GA)]. This indicates successful detection of all ILND cases and that none of the ILND cases was misclassified (i.e., bringing the number of false negative (FN) cases to zero) as shown in the confusion matrix in Table VIII. The reason for SVM outperforming ETC is because in data mining field, it is well known that classifiers with small margins in their decision boundaries such as ETC, tend to be more susceptible to model over-fitting (they perform poorly on previously unseen cases) compared to SVM which maximizes the margin between its decision boundaries by minimizing the objective function in (17).

This present invention introduces a new approach using wavelet design and machine learning in which the filter coefficients of a new wavelet, namely (WGM1.0) specifically designed for islanding detection, are determined using Procrustes analysis. The IEEE 13-bus system is chosen to exemplify, through numerical results, the validity of the proposed concept.

The results have shown that different wavelets may affect the performance of the classification model, which is emphasized by the large variance between accuracy and F-measure values FIGS. 4(a)-4(c).

While Bagging and Boosting show different recall (r) values in case of Coiflets, Daubechies, and Symlets wavelet families, the variance in recall values is eliminated in case of WGM1.0. Using both methods (Bagging and Boosting) provide highest recall accuracy and F-measure values compared to other wavelets. Moreover, the results indicate that the use of SVM classifier with the newly designed wavelet (WGM1.0) can completely eliminate the misclassification error in the testing data set by achieving the highest accuracy and F-measure values FIG. 4(a) and therefore the apparent challenging cases to WGM 1.0 are because of ETC model over-fitting.

This reflects the high adaptability of WGM1.0 to island signal pattern, which has been confirmed by the improvement in classification results obtained by ETC using majority voting scheme.

The foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

With respect to the above description, it is to be realized that the optimum relationships for the parts of the invention in regard to form, materials, function and manner of operation, assembly and use are deemed readily apparent and obvious to those skilled in the art, and all equivalent relationships to those illustrated in the drawings and described in the specification are intended to be encompassed by the present invention.

### Tables:

TABLE I

| New generated wavelet | Proposed name | Dissimilarity Index (d) |
|---|---|---|
| First new wavelet | WGM 1.0 | 0.183887192 |
| Second new wavelet | WGM 1.1 | 0.184066702 |
| Third new wavelet | WGM 1.2 | 0.184124251 |
| Fourth new wavelet | WGM 1.3 | 0.184124522 |

TABLE II

| Low-pass filter (h₀(k)) | High-pass filter (h₁(k)) |
|---|---|
| 0.68556 | 0.49809 |
| −0.22276 | −0.16184 |
| −0.14209 | 0.43177 |
| 0.43177 | 0.14209 |
| 0.16184 | −0.22276 |
| 0.49809 | −0.68556 |

TABLE III

| | | Switch Status | | |
|---|---|---|---|---|
| Islanding Scenario | DGs in the Island | S1 | S4 | S5 |
| First scenario | DG1 | Closed | Open | Open |
| Second scenario | DG1 and DG2 | Closed | Closed | Open |
| Third scenario | DG1 and DG3 | Closed | Open | closed |

TABLE IV

Predicted Class

| | | ILND | NILND |
|---|---|---|---|
| Actual | ILND | 99 (TP) | 44 (FN) |
| Class | NILND | 0 (FP) | 330 (TN) |

TABLE V

| Wavelet-based | |
|---|---|
| SVM model | Confidence Interval |
| COIF 3 | 0.801235-0.867731 |
| COIF 5 | 0.930597-0.969096 |
| DB 4 | 0.751769-0.824947 |
| DB 10 | 0.826362-0.88829 |
| SYM 4 | 0.903602-0.949866 |
| SYM 8 | 0.903602-0.949866 |
| SYM 10 | 0.877447-0.929995 |
| WGM1.0 | 0.991944-1.000000 |

TABLE VI

| Wavelet-based | |
|---|---|
| ETC model | Confidence Interval |
| COIF 3 | 0.877421-0.929974 |
| COIF 5 | 0.930583-0.969086 |
| DB 4 | 0.751766-0.824944 |
| DB 10 | 0.930583-0.969086 |
| SYM 4 | 0.751766-0.824944 |
| SYM 8 | 0.826324-0.888797 |
| SYM 10 | 0.776404-0.846444 |
| WGM1.0 | 0.958840-0.986965 |

TABLE VII

| Wavelet-based | |
|---|---|
| ETC model | Confidence Interval |
| COIF 3 | 0.8541691-0.909567 |
| COIF 5 | 0.7030006-0.781430 |
| DB 4 | 0.727307-0.803267 |
| DB 10 | 0.776404-0.846444 |
| SYM 4 | 0.727307-0.803267 |
| SYM 8 | 0.776404-0.846444 |
| SYM 10 | 0.801245-0.867739 |
| WGM1.0 | 0.958840-0.986965 |

TABLE VIII

Predicted Class

| | | ILND | NILND |
|---|---|---|---|
| Actual | ILND | 143(TP) | 0 (FN) |
| Class | NILND | 0 (FP) | 330 (TN) |

TABLE IX

| | Inverter-based | | Inverter-based | | Synchronous | |
|---|---|---|---|---|---|---|
| | DG1 at Bus | | DG2 at Bus | | DG3 at Bus | |
| DG Parameter | 671 | | 634 | | 671 | |
| Nominal Power | 2 | MW | 0.6 | MW | 0.6 | MW |
| Nominal Voltage | 690 | V | 690 | V | 690 | V |
| Nominal Frequency | 60 | Hz | 60 | Hz | 60 | Hz |
| Stator Resistance | 0.0054 | pu | 0.0054 | pu | 0.0054 | pu |
| Rotor Resistance | 0.00607 | pu | 0.00607 | pu | 0.00607 | pu |
| Stator Leakage | 0.1 | pu | 0.1 | pu | 0.1 | pu |
| Reactance | | | | | | |
| Magnetizing | 4.5 | pu | 4.5 | pu | 3.86 | pu |
| Reactance | | | | | | |
| Rotor Leakage | 0.11 | pu | 0.11 | pu | 0.122 | pu |
| Reactance | | | | | | |

1. A method for electrical power signal pattern detection using intelligent single point monitoring applied to islanding phenomenon in electric power distribution systems embedded with distributed generation comprising:
a) designing a wavelet;
b) performing Procrustes analysis of said wavelet;
c) measuring a 3-phase voltage from an electrical signal to obtain a mean voltage (vₘₑₐₙ);
d) comparing said wavelet to said mean voltage;
e) selecting said wavelet with a lowest dissimilarity index;
f) determining a detail level and approximation coefficients by applying a wavelet transform to said mean voltage;
g) determining a change in said wavelet coefficients at said detail level and said approximation levels; and
h) computing the energy of said change in said wavelet coefficients of voltage,
whereby said energy of said change wavelet coefficients gives indication of an occurrence of islanding.

2. The method of claim 1, wherein designing of said wavelet is accomplished by ψ(t)=Σₖh₁(k)\sqrt{2}φ(2t−k), wherein ψ(t) being a wavelet function, h₁(k) being a high pass filter, φ being a scaling function of the wavelet transform.

3. The method of claim 1, wherein said wavelet having a low pass filter.

4. The method of claim 3, wherein said low pass filter having minimum conditions comprising:
a) normalizing accomplished by
Σₖ^{h}^{₀}^{²}^{(k)=1}
h₀²(0)+h₀²(1)+h₀²(2)+h₀²(3)+h₀²(4)+h₀²(5)=1;
b) determining a double shift orthagonality by
Σₖh₀(k)h₀(k−2n)=0for n≠0;
h₀(0)h₀(2)+h₀(1)h₀(3)+h₀(2)h₀(4)+h₀(3)h₀(5)=0; and
c) determining a low pass by
Σₖ^{(-1)k h}^{₀}^{(k)=0}
h₀(0)−h₀(1)+h₀(2)−h₀(3)+h₀(4)−h₀(5)=0,
wherein, h₀(k) being the low pass filter.

5. The method of claim 1, wherein said dissimilarity index being determined by
$$d = \frac{{\sum }_{v} {( {u}_{v} - {v}_{v} )}^{2}}{{\sum }_{v} {( {u}_{v} - μ )}^{2}}$$
wherein u being a target shape from an island signal, v being a transformed shape of the wavelet function, μ being the mean of the target shape.

6. The method of claim 1, wherein measuring a 3 phase voltage to obtain a mean voltage(vₘₑₐₙ) is accomplished by:
$${v}_{mean} ( n ) = \frac{( {v}_{R} ( n ) + {v}_{S} ( n ) + {v}_{T} ( n ) )}{3}$$
wherein R, S and T being phase labels, v being a transformed shape of the wavelet function.

7. The method of claim 1, wherein applying said wavelet transform to said mean voltage is accomplished by
cDⱼ⁽ⁱ⁾= [symbol] vₘₑₐₙ,ψ_{j,i} [symbol] and cAⱼ⁽ⁱ⁾= [symbol] vₘₑₐₙ,φ_{j,i} [symbol] ,
wherein j being the decomposition level index, wherein ψ(t) being a wavelet function, φ being the scaling function of the wavelet transform, i being the index of the wavelet coefficients.

8. The method of claim 1, wherein determining the change in said wavelet coefficients at detail level is accomplished by:
COMVⱼ^{D}(i)=cDⱼ(i)−cDⱼ(i−1),
wherein j being the decomposition level index, cDⱼ being said detail level coefficient.

9. The method of claim 1, wherein determining the change in said wavelet coefficients at approximation level is accomplished by:
COMVⱼ^{A}(i)=cAⱼ(i)−cAⱼ(i−1),
wherein j being the decomposition level index, cAⱼ being said approximation level coefficient.

10. The method of claim 1, wherein computing said energy of change in said wavelet coefficients voltage is accomplished by
E_{COMV}_{ⱼ}_{^{D}}=Σ_{I}|COMVⱼ^{D}(i)|² and E_{COMV}_{ⱼ}_{^{A}}=Σ_{I}|COMVⱼ^{A}(i)|²
wherein j being the decomposition level index, COMVⱼ^{D} being said change in detail level coefficient, COMVⱼ^{A} being said change in approximation level coefficient.

11. A device for electrical power signal pattern detection using intelligent single point monitoring applied to islanding phenomenon in electric power distribution systems embedded with distributed generation comprising:
a. a processor; and
b. a computer code to cause the device to perform at least the following:
a) designing a wavelet;
b) performing Procrustes analysis of said wavelet;
c) measuring a 3-phase voltage from an electrical signal to obtain a mean voltage (vₘₑₐₙ);
d) comparing said wavelet to said mean voltage;
e) selecting said wavelet with a lowest dissimilarity index;
f) determining a detail level and approximation coefficients by applying a wavelet transform to said mean voltage;
g) determining a change in said wavelet coefficients at said detail level and said approximation levels; and
h) computing the energy of said change in said wavelet coefficients of voltage,
whereby said energy of said change wavelet coefficients gives indication of an occurrence of islanding.

12. The device of claim 11, wherein designing of said wavelet is accomplished by ψ(t)=Σₖh₁(k)\sqrt{2}φ(2t−k), wherein ψ(t) being a wavelet function, h₁(k) being a high pass filter, φ being a scaling function of the wavelet transform.

13. The device of claim 11, wherein said wavelet having a low pass filter.

14. The device of claim 13, wherein said low pass filter having minimum conditions comprising:
a) normalizing accomplished by
Σₖ^{h}^{₀}^{²}^{(k)=1}
h₀²(0)=h₀²(1)+h₀²(2)=h₀²(3)+h₀²(4)+h₀²(5)=1;
b) determining a double shift orthagonality by
Σₖh₀(k)h₀(k−2n)=0 for n≠0;
h₀(0)+h₀(2)+h₀(1)+h₀(3)+h₀(2)h₀(4)+h₀(3)h₀(5)=0; and
c) determining a low pass by
Σₖ⁽⁻¹⁾^{^{k}}^{h}^{₀}^{(k)=0}
h₀(0)−h₀(1)+h₀(2)−h₀(3)+h₀(4)−h₀(5)=0,
wherein, h₀(k) being the low pass filter.

15. The device of claim 11, wherein said dissimilarity index being determined by:
$$d = \frac{{\sum }_{v} {( {u}_{v} - {v}_{v} )}^{2}}{{\sum }_{v} {( {u}_{v} - μ )}^{2}}$$
wherein u being a target shape from an island signal, v being a transformed shape of the wavelet function, μ being the mean of the target shape.

16. The device of claim 11, wherein measuring a 3 phase voltage to obtain a mean voltage(vₘₑₐₙ) is accomplished by
$${v}_{mean} ( n ) = \frac{( {v}_{R} ( n ) + {v}_{S} ( n ) + {v}_{T} ( n ) )}{3}$$
wherein R, S and T being phase labels, v being a transformed shape of the wavelet function.

17. The device of claim 11, wherein applying said wavelet transform to said mean voltage is accomplished by
cDⱼ⁽ⁱ⁾= [symbol] vₘₑₐₙ,ψ_{j,i} [symbol] and cAⱼ⁽ⁱ⁾= [symbol] vₘₑₐₙ,φ_{j,i} [symbol] ,
wherein j being the decomposition level index, wherein ψ(t) being a wavelet function, φ being the scaling function of the wavelet transform, i being the index of the wavelet coefficients

18. The device of claim 11, wherein determining the change in said wavelet coefficients at detail level is accomplished by
COMVⱼ^{D}(i)=cDⱼ(i)−cDⱼ(i−1),
wherein j being the decomposition level index, cDⱼ being said detail level coefficient.

19. The device of claim 11, wherein determining the change in said wavelet coefficients at approximation level is accomplished by
COMVⱼ^{A}(i)=cAⱼ(i)−cAⱼ(i−1),
wherein j being the decomposition level index, cAⱼ being said approximation level coefficient.

20. The device of claim 11, wherein computing said energy of change in said wavelet coefficients voltage is accomplished by
E_{COMV}_{ⱼ}_{^{D}}=E_{I}|COMVⱼ^{D}(i)|² and E_{COMV}_{ⱼ}_{^{A}}=Σ_{I}|COMVⱼ^{A}(i)|²
wherein j being the decomposition level index, COMVⱼ^{D} being said change in detail level coefficient, COMVⱼ^{A} being said change in approximation level coefficient.
